(19) United States
(12) Patent Application Publication
(10) Pub. No.: US 2010/0329298 A1
(43) Pub. Date: Dec. 30, 2010

(54) INTRACAVITY FREQUENCY-CONVERTED SOLID-STATE LASER FOR THE VISIBLE WAVELENGTH REGION

(75) Inventors: Ulrich Weichmann, Aachen (DE); Holger Moench, Vaals (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/446,472

(22) PCT Filed: Oct. 15, 2007
(86) PCT No.: PCT/IB07/54186

§ 371 Date: Apr. 21, 2009

(30) Foreign Application Priority Data
Oct. 24, 2006 (EP) 06122827.6

(51) Int. Cl. H01S 5/40; H01S 3/16

(52) U.S. Cl. 372/50.121; 372/68

(57) ABSTRACT

The present invention provides an intracavity frequency-converted solid state laser for the visible wavelength region. The laser comprises a semiconductor laser (1) with an extended laser cavity (2). A second laser cavity (4) is formed inside of said extended laser cavity (2). The second laser cavity (4) comprises a gain medium (3) absorbing radiation of the semiconductor laser (1) and emitting radiation at a higher wavelength in the visible wavelength region. The frequency converting gain medium (3) is formed of a rare-earth doped solid state host material. The proposed laser can be manufactured in a highly integrated manner for generating radiation in the visible wavelength region, for example in the green, red or blue wavelength region.

### TECHNICAL FIELD

The present invention relates to an intracavity frequency-converted solid state laser comprising a semiconductor laser with an extended laser cavity, in particular a GaN-laser.

The inherent high radiance of lasers makes them an ideal candidate as the light source for applications with high optical demands. The possible high integration of semiconductor lasers is highly advantageous for applications which require small sized high intensity light sources, for example to replace UHP-lamps in projection. For such an application, lasers emitting in the blue, green and red wavelength region (RGB) are necessary. However, until now, integrated green lasers are not available.

### BACKGROUND OF THE INVENTION

The lack of integrated laser sources in the green wavelength region has until now hindered the widespread use of lasers for display or illumination applications. Nowadays used laser sources for the green wavelength region rely on frequency conversion either by upconversion or by second harmonic generation (SHG) of an infrared laser source.

An alternative to upconversion from the infrared wavelength region is the frequency conversion of blue laser sources. With the recent development of GaN-based laser diodes for the blue-violet region this scheme becomes even attractive for all-solid state devices at visible wavelengths.

US 2005/0265411 A1 describes a diode-pumped solid state laser including a short wavelength semiconductor laser that pumps an absorption transition in a rare-earth doped material. The laser diode pump source may comprise a GaN-based semiconductor laser. The separate solid state laser is based on a glass or crystalline host material doped with rare-earth ions. The rare-earth based solid state laser absorbs the radiation emitted by the GaN-laser diode and emits the desired radiation in the visible wavelength range.

### SUMMARY OF THE INVENTION

It is an object of the present invention to provide a solid state laser emitting in the visible wavelength region which can be manufactured in a highly integrated manner.

The object is achieved with the intracavity frequency-converted solid state laser according to claim 1. Advantageous embodiments of this solid state laser are subject matter of the subclaims or are described in the following description and embodiments for carrying out the invention.

The proposed intracavity frequency-converted solid state laser comprises a semiconductor laser with an extended laser cavity. A second laser cavity is arranged inside of said extended laser cavity. The second laser cavity contains a gain medium absorbing the radiation of the semiconductor laser and emitting radiation at a higher wavelength in the visible wavelength region, i.e. downconverting the radiation of the semiconductor laser to lower photon energies. The gain medium in the second laser cavity is formed of a solid state host material doped with appropriate rare-earth ions.

Therefore, the present invention proposes a highly integrated solid state laser for the visible wavelength region based on intracavity frequency-conversion of a semiconductor laser, preferably of a GaN-based diode laser. The semiconductor laser is operated with an extended cavity. Inside this extended cavity, a rare-earth ion doped solid state material absorbs a part of the pump radiation of the semiconductor laser and emits radiation in the visible wavelength range. The emission wavelength of this solid state material depends on the chosen rare-earth ion(s) and the reflectance of the laser mirrors of the second laser cavity. Pump radiation from the semiconductor laser, which is not absorbed in the rare-earth doped material, is reflected back into the semiconductor laser gain material and serves as feedback for the pump laser.

The gain medium of the second laser cavity, i.e. the rare-earth ion doped solid state material, is selected according to the wavelengths of the semiconductor laser used as a pump laser and the desired emitting wavelength of the proposed solid state laser. Appropriate semiconductor lasers and rare-earth doped hosts are known in the art. When using GaN-based pump lasers, which typically emit at wavelengths between 380 and 480 nm, different rare-earth ions in several host materials can be used for the frequency conversion towards red, green or blue. Very efficient materials for red wavelengths are Pr³⁺-doped fluorides like ZBLAN, CaF₂, LiLuF₄ or YLF, which can be pumped by GaN-based laser diodes and emit most efficiently on the red transition at 635 nm. A less efficient transition in Pr³⁺ can be used to emit green laser radiation around 520 nm. Another ion for the generation of green laser radiation is Tb³⁺, emitting at a wavelength of 542 nm. This ion can be incorporated into different host materials and pumped directly by a GaN-based pump laser at 380 nm. Other examples are Tb:YAG or Pr:YAlO₃. Furthermore co-doped materials, in particular co-doped Tb-materials, can be used to achieve the desired visible wavelength, for example a combination of Ce and Tb or a combination of Dy and Tb for the green wavelength region. The generation of other wavelengths than red and green is of course also possible by choosing other rare-earth ions or combinations of rare-earth ions.

In an advantageous embodiment of the proposed solid state laser the host material for the second gain medium is a GaN-based material which provides the possibility of a complete integration of the solid state laser on a wafer level. In this embodiment, with a GaN-based semiconductor laser, a highly integrated solid state laser is achieved. The use of a GaN-based host material for the rare-earth ions ensures compatibility with the materials and processes used to produce the GaN-diode pump laser itself In this context the term GaN-based should include GaN-materials which may contain a fraction of other materials, for example Al or In, typically in concentrations of a few % up to above 10%.

The semiconductor laser is preferably designed as an edge emitting laser and arranged on a common substrate together with the downconverting gain medium. In an advantageous embodiment, the gain medium of the semiconductor laser and the downconverting gain medium form waveguides for the semiconductor laser radiation and the downconverted radiation. In order to ensure a sufficiently high intensity of the semiconductor laser radiation inside of the downconverting gain medium, the waveguide structure formed of the downconverting gain medium has a smaller cross section than the waveguide formed of the semiconductor gain medium. Both waveguides are preferably connected by a tapered region.

The use of rare-earth ions allows for a wide choice of visible laser wavelengths in combination with optical pumping at the optimum efficiency of the semiconductor laser, in particular of a GaN-laser diode. The preferred choice of GaN as a host material for these ions allows the integration of the laser on a wafer level both for a single wavelength device as well as for an RGB laser source. The embodiment of the RGB laser source is realized by arranging at least three of the proposed solid state lasers side by side on a common substrate and selecting different dopants for the downconverting gain material of the three lasers in combination with appropriate mirrors of the second laser cavity. Due to the concept of intracavity pumping the fraction of the pump power, which is not absorbed, is not lost, but fed back into the laser diodes. This allows lower rare-earth doping or shorter waveguide structures.

These and other aspects of the invention will be apparent from and elucidated with reference to the embodiments described herein after.

### BRIEF DESCRIPTION OF THE DRAWINGS

The proposed intracavity frequency-converted solid state laser is described in the following by way of examples in connection with the accompanying figures without limiting the scope of protection as defined by the claims. The figures show:

FIG. 1 an example of a basic layout of the intracavity frequency-converted solid state laser; and

FIG. 2 a top view of a further example of the intracavity frequency-converted solid state laser.

### EMBODIMENTS FOR CARRYING OUT THE INVENTION

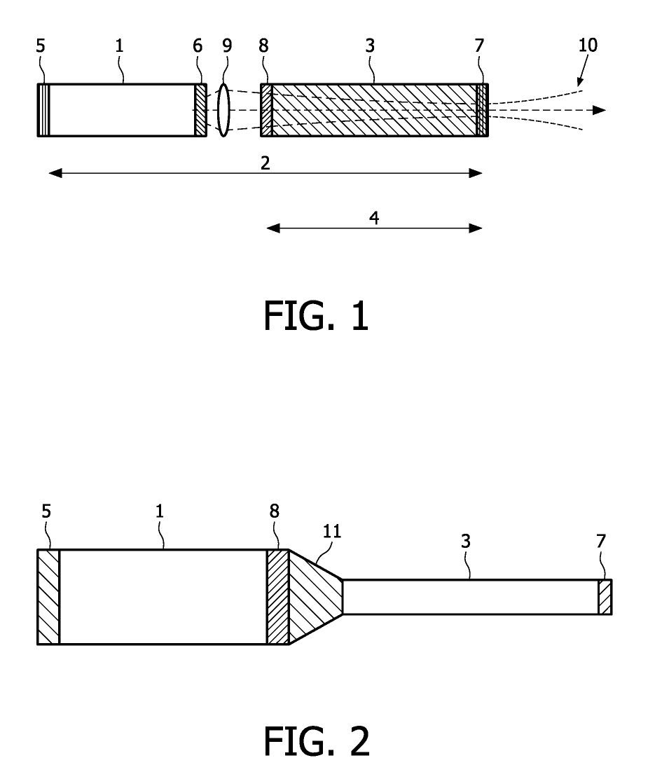

An example of a basic layout of the proposed solid state laser is sketched in FIG. 1. The solid state laser comprises a GaN-based laser diode 1, one end surface of which has an antireflection coating 6 for a wavelength of the GaN-based laser diode 1, i.e. for the pump radiation. The cavity of the GaN-based laser diode 1 comprises end mirrors 5 and 7 which form an extended pump laser cavity 2. These mirrors 5 and 7 are high reflectivity mirrors for the pump radiation. The radiation from the laser diode 1 is collimated by some optics 9 and focused into a block of downconverting material 3, which absorbs part of the pump radiation and converts the frequency towards the visible wavelength region. This downconverting material 3 is a rare-earth doped solid state material, for example Tb:GaN, Pr:GaN, Pr:ZBLAN or Tb:YAG.

One end of this block of converting material 3 carries a coating 8 which is highly reflective for the visible wavelengths generated by downconverting and antireflective for the pump radiation. The other end of this block is coated with mirror 7 which not only is highly reflective for the pump radiation but also reflects the visible wavelengths, at the same time ensuring that a portion of the radiation of the visible wavelengths is coupled out through this mirror 7. The mirror 7 therefore forms a resonator mirror of the pump laser cavity 2 and a resonator mirror of the visible laser cavity 4 (together with mirror 8) and serves as output coupler for the visible laser cavity 4 (visible output 10).

The reflectivity of antireflective coating 6 on one end surface of the GaN laser diode 1 can also be chosen >0 to increase feedback. This reflectivity on the other hand must be low enough to ensure, that the GaN-based diode laser 1 does not lase within a shorter cavity than the extended pump laser cavity 2.

The GaN-based laser diode 1 together with the converting material 3 are arranged on a common substrate and formed as waveguide structures as known in the art for GaN-based laser diodes. In such a waveguide structure the active material (gain material) of the GaN-based laser diode is sandwiched between layers of materials with a lower refractive index to form the waveguide structure. Methods for manufacturing such a GaN-based laser diode, in particular as an edge emitting laser, are known in the art.

FIG. 2 shows a fully integrated setup of the intracavity frequency-converted visible solid state laser in a top view as FIG. 1. The solid state laser comprises the GaN-based pump laser 1 and the layer of wavelength converting material 3 which form waveguides on a common substrate. The GaN-based pump laser has a pump laser cavity 2 between end mirror 5 and end mirror 7, both highly reflective for the pump radiation. End mirror 7 at the same time serves as an output coupler for the converted radiation. The laser cavity of the visible laser is formed of this mirror 7, reflecting a portion of the visible radiation and mirror 8, which is highly reflective for the visible radiation and forms an antireflective coating for the pump radiation.

The wavelength converting layer in this embodiment has the form of a waveguide with a tapered region 11 between the GaN-based pump laser diode 1 and the waveguide layer of wavelength converting material 3. Such a tapered structure allows for a low threshold and high efficiency of the visible laser. In this embodiment, the host of the wavelength converting material 3 is a GaN-based material. For green laser action the converting material 3 may be for example Tb:GaN or Pr:GaN. Tb-ions are especially suited for the incorporation in a material with high phonon energy, since the upper laser level is well isolated from the lower lying levels and non radiative losses are therefore not of importance for this ion. Tb is therefore an ideal candidate for incorporation into GaN-material allowing an integration of the proposed solid state laser on a wafer level.

In another embodiment, a laser with the same construction as that of FIG. 2 can be realized with a non-GaN-based host material but still highly integrated. Such a structure can be prepared on a GaN-based wafer during wafer processing. In a separate step after wafer processing the rare-earth doped material is deposited on top of the structure. The features of the GaN structure define a waveguide including the mirrors like for example DBR's (Distributed Feedback Reflectors).

The integration on a wafer level allows an economic fabrication of RGB laser sources. This can be achieved by manufacturing three of the solid state lasers, for example each according to FIG. 2, side by side on a wafer substrate, wherein each of the three wavelength converting layers is doped with a different rare-earth ion for generating red, green and blue light. When processing such a solid state laser at wafer level, a multiplicity of RGB sources can be manufactured at the same time on the wafer. The provision of such a full integration of red, green and blue in one laser source is of major importance for future applications like projection or fiber optical illumination.

While the invention has been illustrated and described in detail in the drawings and foregoing description, such illustration and description are to be considered illustrative or exemplary and not restrictive; the invention is not limited to the disclosed embodiments. The different embodiments described above and in the claims can also be combined.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope of these claims.

### LIST OF REFERENCE SIGNS

1 GaN-based laser diode
2 pump laser cavity
3 converting material
4 visible laser cavity
5 first end mirror of pump laser cavity
6 antireflective coating for pump laser radiation
7 second end mirror of pump laser cavity
8 end mirror of visible laser cavity
9 optics
10 visible output
11 tapered region

1. Intracavity frequency-converted solid state laser, comprising:
a semiconductor laser defining an extended laser cavity and a second laser cavity arranged within said extended laser cavity, said second laser cavity containing a gain medium absorbing radiation of the semiconductor laser and emitting radiation at a higher wavelength in the visible wavelength region, wherein said gain medium in the second laser cavity is formed of a solid state host material doped with rare-earth ions.

2. Solid state laser according to claim 1, wherein said semiconductor laser is a GaN laser.

3. Solid state laser according to claim 2, wherein the host material of the second gain medium is a GaN based material.

4. Solid state laser according to claim 1, wherein a gain medium of the semiconductor laser and the gain medium of the second laser cavity form waveguides.

5. Solid state laser according to claim 4, wherein the waveguide of the gain medium of the second laser cavity has a smaller cross section than the waveguide of the gain medium of the semiconductor laser, both waveguides being connected through a tapered region.

6. RGB light source comprising at least three solid state lasers according to claim 1, said three solid state lasers emitting at different wavelengths in the red, green and blue wavelength region and being fabricated on a common substrate.
